(19) United States
(12) Patent Application Publication
(10) Pub. No.: US 2009/0294279 A1
(43) Pub. Date: Dec. 3, 2009

(54) SPUTTERING APPARATUS AND FILM FORMING METHOD

(75) Inventors: Yukio Kikuchi, Tsukuba-shi (JP); Tadashi Morita, Tsukuba-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Kanagawa-ken (JP)

(21) Appl. No.: 11/813,813

(22) PCT Filed: Jan. 17, 2006
(86) PCT No.: PCT/JP2006/300548

§ 371 Date: Aug. 17, 2009

(30) Foreign Application Priority Data
Jan. 19, 2005 (JP) 2005-011364

(51) Int. Cl. C23C 14/34

(52) U.S. Cl. 204/192.15; 204/298.15; 204/298.11; 204/192.12

(57) ABSTRACT

A sputtering apparatus for performing a film forming process on a substrate surface of a disk-like substrate while rotating the substrate around a rotation axis line, the sputtering apparatus including a chamber, a table that rotates the substrate around the rotation axis line, and a sputtering cathode that has a cathode surface facing the substrate. Assuming that a distance between the rotation axis line and a peripheral edge of the substrate is R, a distance between the rotation axis line and a center point of the cathode surface is OF, and a height from the substrate surface to the center point of the cathode surface is TS, the following relationship is substantially satisfied:

R:OF:TS=100:175:190±20.

In addition, the rotation axis line intersects a normal line passing through the center point of the cathode surface, and an intersection angle thereof falls within a range of 22°±2°.

### TECHNICAL FIELD

The present invention relates to a method of manufacturing a magnetic multi-layered film that is adapted to formation of a film constituting a semiconductor device, such as a Giant Magneto-Resistance (GMR) spin valve constituting a magnetic head, and a Tunneling Magneto-Resistance (TMR) device constituting a magnetic random access memory (MRAM).

Priority is claimed on Japanese Patent Application No. 2005-011364, filed on Jan. 19, 2005, the contents of which are incorporated herein by reference.

### BACKGROUND ART

A sputtering apparatus has been widely used as a film forming apparatus. In general, a sputtering apparatus has a processing chamber in which a table on which a substrate to be processed is placed and a sputter cathode (target) on which a film forming material is placed are arranged. Patent Document 1 discloses that a film can be uniform in its thickness and quality by rotating the substrate at a suitable speed and maintaining an angle θ of a center axis line of the target with respect to a normal line of the substrate to fall within a range of 15°≦θ≦45° even if the target is smaller in diameter than the substrate.

[Patent Document 1] Japanese Unexamined Patent Application, First Publication No. 2000-265263

### DISCLOSURE OF THE INVENTION

### [Problems to be Solved by the Invention]

In recent years, a tunnel junction device 10 as shown in FIG. 5A has been employed with a semiconductor device such as an MRAM under development. The tunnel junction device 10 includes a magnetic layer (fixed layer) 14, a tunnel barrier layer 15, a magnetic layer (free layer) 16, and so on. The tunnel barrier layer 15 is made of AlO (representing aluminum oxide in general, including alumina) obtained by oxidizing Al (metal aluminum). A binary value ‘1’ or ‘0’ is read by using the resistance of the tunnel junction device 10, which is varied depending on whether a magnetization direction of the fixed layer 14 is parallel or anti-parallel to a magnetization direction of the free layer 16.

As shown in FIG. 5B, if there is a deviation in film thickness in each layer (for example, the free layer 16) of the tunnel junction device 10, the tunnel barrier layer 15 is laminated with unevenness. Since the tunnel resistance of the tunnel barrier layer 15 depends on its thickness exponentially, the tunnel resistance has a large deviation of more than 10% even if the thickness deviation of the tunnel barrier layer 15 is 1%. In addition, since the MRAM device (tunnel junction device) is fabricated from a large substrate having a size of not less than 8 inches, a gross deviation of the resistance of the MRAM device according to the positions on the substrate causes big problem in mass production. Similarly, if the free layer 16 has deviation in its thickness, magnetization of the free layer 16 is varied depending on positions on the substrate, which results in irregularity of an applied magnetic field when magnetization of a processed MRAM device is reversed. These problems are concerned with the performance of the MRAM device. Accordingly, there is a need to reduce the deviation in thickness of the layers of the tunnel junction device 10.

However, in a conventional sputtering apparatus, particles emitted from the target reach the substrate after being scattered by collision with sputter gas molecules such as argon gas. This makes it difficult to obtain a uniform film thickness even when performing a film forming process while rotating the substrate, depending on a relative position between the target and the substrate or a distance between the substrate and a wall of the chamber.

Particularly, with a large substrate having a size of more than 8 inches, it is very difficult to obtain a uniform film thickness. Also, in the technique disclosed in Patent Document 1, it is difficult to obtain a film thickness having deviation of equal to or less than 1%.

To overcome the above problems, it is an object of the present invention to provide a sputtering apparatus and a film forming method, which are capable of reducing deviation in film thickness.

### [Means for Solving the Problems]

In order to achieve the above-mentioned object, according to an aspect, there is provided a sputtering apparatus for performing a film forming process on a substrate surface of a disk-like substrate while rotating the substrate around a rotation axis line, the sputtering apparatus including a chamber having a sputter processing chamber formed therein, a table that is provided in a first region of the chamber and rotates the substrate in a plane parallel to the substrate surface around the rotation axis line while holding the substrate with the substrate surface directed toward the sputter processing chamber, and a sputtering cathode that is provided at a position spaced from the rotation axis line in a second region of the chamber, the second region being located at the opposite side to the first region with the sputter processing chamber interposed therebetween, and has a cathode surface facing the substrate in the sputter processing chamber. Assuming that a distance between the rotation axis line and a peripheral edge of the substrate is R, a distance between the rotation axis line and a center point of the cathode surface is OF, and a height from the substrate surface to the center point of the cathode surface is TS, the following relationship is substantially satisfied,

R:OF:TS=100:175:190±20.

In addition, the rotation axis line intersects a normal line passing through the center point of the cathode surface, and an intersection angle falls within a range of 22°±2°.

With this configuration, the film forming process can be performed so that a difference between deviations of film thickness is not more than 1% for various kinds of materials.

In addition, “substantially” means a deviation of 5% or so of the ratio of R:OF:TS from the above relationship, and a value of OF is 175±10 or so.

Preferably, a shield plate which surrounds the substrate is arranged with axial symmetry around the rotation axis line, and the sputter processing chamber is disposed in an inner space surrounded by the shield plate and the substrate surface.

With this configuration, the shield plate can provide axial symmetry to an effect on the deviation of the film thickness; thereby the deviation in the film thickness can be reduced.

Preferably, the shield plate includes a first shield plate that has a cylindrical shape and extends from the second region to the first region, and a second shield plate that has a funnel shape and extends from an end portion of the first shield plate in the first region to the peripheral edge of the substrate, and an inclined angle of the second shield plate with respect to the substrate surface is set to equal to or less than 0° and equal to or less than 20°.

With this configuration, a deviation in film thickness at the peripheral edge of the substrate, which occurs due to the second shield plate, can be reduced.

Further, according to the present invention, there is provided a film forming method using the above sputtering apparatus, including a vacuum forming step of vacuumizing the sputter processing chamber with the substrate being placed on the table, and a film forming step of forming the film on the substrate surface by introducing a sputter gas into the sputter processing chamber to generate plasma while rotating the substrate using the table.

With this configuration, the film forming process can be performed so that a difference between deviations of film thickness is not more than 1% for various kinds of materials.

Preferably, the substrate is rotated with the rotational speed of equal to or more than 30 rpm.

With this configuration, even if a film is formed to be thin at a relatively low film forming speed, in a range of practical film forming conditions, a deviation in the film thickness in the circumference of the substrate can be averaged. Accordingly, the deviation in the film thickness can be reduced.

Furthermore, a multi-layered film including a magnetic layer may be formed in the film forming step.

For a multi-layered film including a magnetic layer, there is a strong need to reduce a deviation in the film thickness. Accordingly, a magnetic multi-layered film having good characteristics can be formed using the above film forming method.

### EFFECTS OF THE INVENTION

According to the present invention, with the above configuration, a film forming process from various kinds of materials can be performed so that a deviation in film thickness is not more than 1%.

### BRIEF DESCRIPTION OF THE DRAWINGS

FIG. 1A is a perspective view of a sputtering apparatus according to an embodiment of the present invention.

FIG. 1B is a side sectional view of the sputtering apparatus according to the embodiment of the present invention.

FIG. 2 is an enlarged view of portion B of FIG. 1B.

FIG. 3A is a graph showing a relationship between tilt angle θ of a target and a film thickness deviation.

FIG. 3B is a graph showing a relationship between tilt angle θ of a target and a film thickness deviation.

FIG. 3C is a graph showing a relationship between tilt angle θ of a target and a film thickness deviation.

FIG. 4A is a schematic view showing a configuration of a tunnel junction device.

FIG. 4B is a schematic view showing a configuration of an MRAM having the tunnel junction device.

FIG. 5A is an explanatory view of a Neel coupling.

FIG. 5B is an explanatory view of a Neel coupling.

### REFERENCE SYMBOLS

5: Substrate
60: Sputtering apparatus
61: Chamber
62: Table
62a: Rotation axis line
64: Target (sputtering cathode)
64a: Normal line
70: Sputter processing chamber
71: Side shield plate (shield plate, first shield plate)
72: Lower shield plate (shield plate, second shield plate)

### BEST MODE FOR CARRYING OUT THE INVENTION

Hereinafter, an embodiment of the present invention will be described with reference to the accompanying drawings. Throughout the figures used in the following description, layers and members are scaled to a perceivable size.

(Magnetic Multi-Layered Film)

First, a tunnel junction device having a TMR film as an example of a multi-layered film including a magnetic layer, and an MRAM including the tunnel junction device will be described.

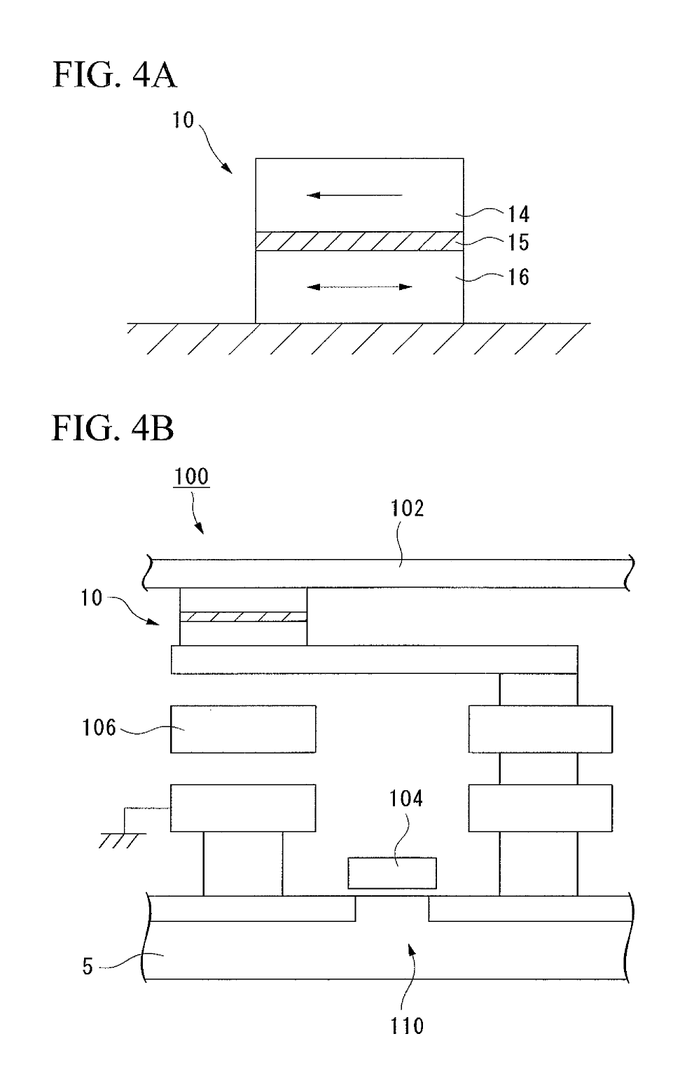

FIG. 4A is a side sectional view showing a tunnel junction device. A tunnel junction device 10 includes an anti-ferromagnetic layer (not shown) made of PtMn, IrMn or the like, a magnetic layer (fixed layer) 14 made of NiFe, CoFe or the like, a tunnel barrier layer 15 made of AlO or the like, and a magnetic layer (free layer) 16 made of NiFe, CoFe or the like, as main components. The tunnel barrier layer 15 made of AlO is formed by oxidizing metal aluminum. In addition, an actual tunnel junction device has a multi-layered structure having 15 layers including functional layers in addition to the above-mentioned layers.

FIG. 4B is a view showing a configuration of an MRAM having the tunnel junction device. An MRAM 100 includes the above-described tunnel junction device 10 and a MOSFET (Metal Oxide Semiconductor Field-Effect Transistor) 110, which are arranged in the form of a matrix on a substrate 5. An upper end of the tunnel junction device 10 is connected to a bit line 102, and a lower end thereof is connected to a source electrode or a drain electrode of the MOSFET 110. In addition, a gate electrode of the MOSFET 110 is connected to a readable word line 104. On the other hand, a rewritable word line 106 is arranged below the tunnel junction device 10.

In the tunnel junction device 10 shown in FIG. 4A, a magnetization direction of the fixed layer 14 keeps constant while a magnetization direction of the free layer 16 can be reversed. Resistance of the tunnel junction device 10 is varied depending on whether the magnetization direction of the fixed layer 14 is parallel or anti-parallel to the magnetization direction of the free layer 16, and accordingly, the intensity of current flowing through the tunnel barrier layer 15 is varied when a voltage is applied to the tunnel junction device 10 in its thickness direction (TMR effect). Thus, when the MOSFET 110 is turned on by the readable word line 104 shown in FIG. 4B, a binary value ‘1’ or ‘0’ can be read by detecting the intensity of current.

In addition, the magnetization direction of the free layer can be reversed when a magnetic field is generated by supplying current to the rewritable word line 106. This allows the binary value ‘1’ or ‘0’ to be rewritten.

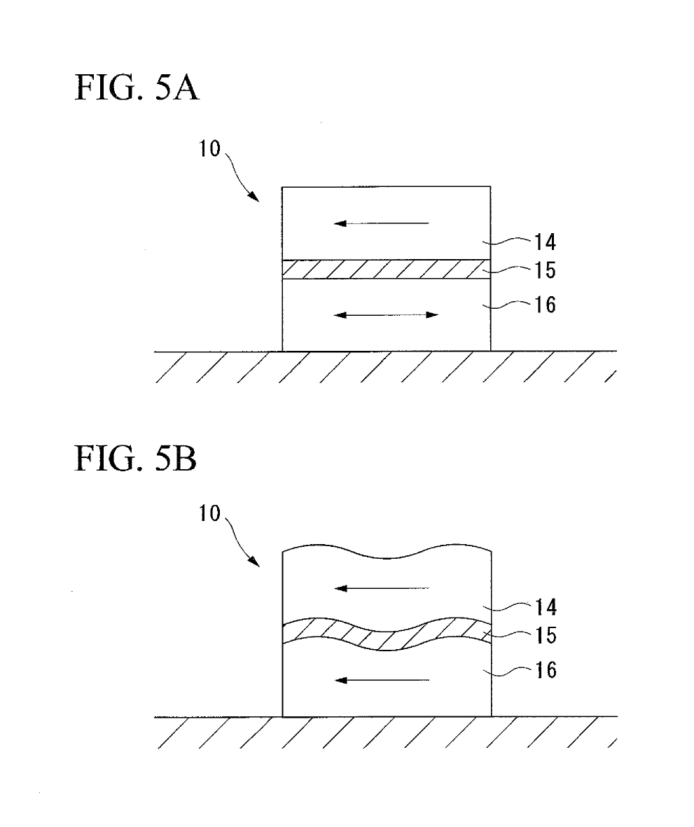

As shown in FIG. 5B, if there is a film thickness deviation in layers (for example, the free layer 16) of the tunnel junction device 10, the tunnel barrier layer 15 is laminated and formed with unevenness. Since tunnel resistance of the tunnel barrier layer 15 depends on its thickness exponentially, the tunnel resistance has a large deviation of not less than 10% even if the film thickness deviation of the tunnel barrier layer is 1%. In addition, since the MRAM device (tunnel junction device) is fabricated from a large substrate having a size of more than 8 inches, a gross deviation of the resistance of the MRAM device according to the positions on the substrate causes big problem in mass production. Similarly, if the free layer 16 has deviation in its thickness, magnetization of the free layer 16 is varied depending on positions on the substrate, which results in irregularity of an applied magnetic field when magnetization of a processed MRAM device is reversed. These problems are concerned with the performance of the MRAM device. Accordingly, there is a need to reduce the deviation in thickness of the layers of the tunnel junction device 10.

(Sputtering Apparatus)

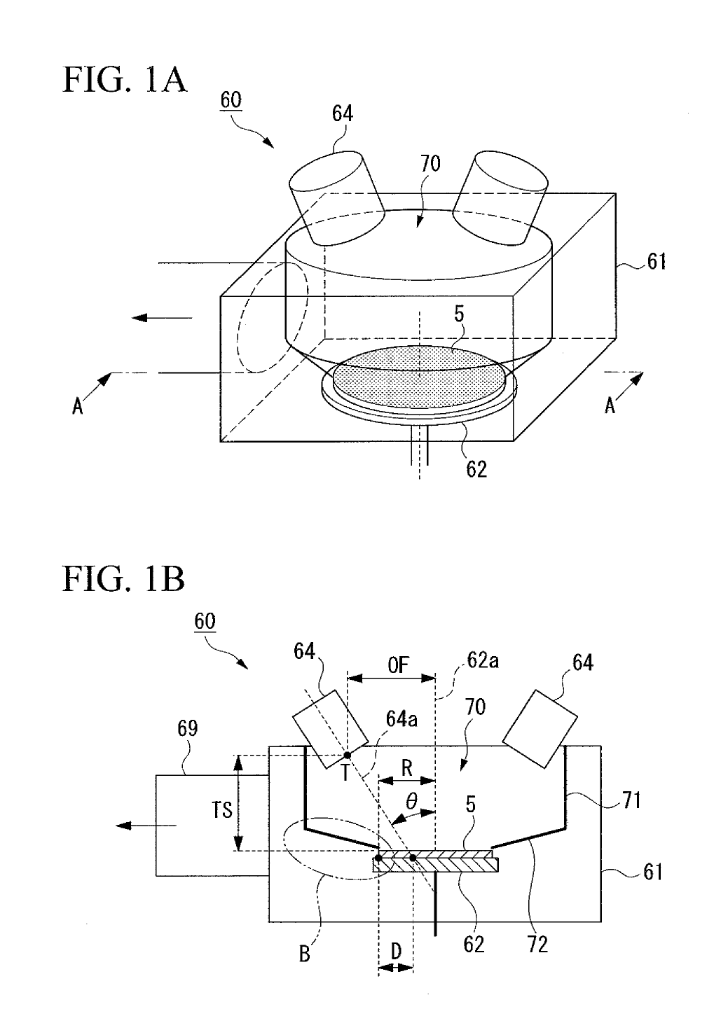

Now, a sputtering apparatus according to an embodiment of the present invention will be described with reference to FIGS. 1A to 3C.

FIG. 1A is a perspective view of a sputtering apparatus according to an embodiment of the present invention, and FIG. 1B is a side sectional view taken along the line A-A of FIG. 1A. A sputtering apparatus 60 according to this embodiment includes a table 62 holding the disk-like substrate 5 by placing it thereon and a target (sputtering cathode) 64, which are arranged at respective predetermined positions. It is preferable that the sputtering apparatus 60 be a magnetron sputtering apparatus having a device for applying a magnetic field to a surface of the target, for example.

As shown in FIG. 1B, the sputtering apparatus 60 has a box-like chamber 61 made of a metal material such as Al. A sputter processing chamber 70 (details of which will be described later) is formed within the chamber 61. The table 62 on which the substrate 5 is placed is provided at a central portion near the bottom, which is a lower region (first region) of the chamber 61. The table 62 is configured to rotate around a rotation axis line 62a with a certain rotational speed. Thus, the placed substrate 5 can be rotated around the rotation axis line 62a in a plane parallel to a surface of the substrate 5 (substrate surface). In addition, the substrate surface can be rotated with the center of the substrate 5 aligned with the rotation axis line 62a.

The target 64 is arranged at an edge near a ceiling, which is an upper region (second region) of the chamber 61. A surface of the target 64 (cathode surface) faces the substrate 5 within the sputter processing chamber 70 (details of which will be described later). A material of a film to be formed on the substrate 5 is placed on the cathode surface. The number of targets 64 may be one or more. If two or more targets 64 are used, it is preferable that these targets 64 be arranged spacing from the rotation axis line 62a of the table 62 at equal intervals around the rotation axis line 62a. With this configuration, deviations of film thickness in the substrate 5 can be reduced. In this embodiment, two targets 64 face each other with the rotation axis line 62a of the table 62 lying therebetween.

The above-described targets 64 are arranged at a predetermined position relative to the substrate 5 placed on the table 62. Here, it is assumed that a distance between the rotation axis line 62a of the table 62 and a peripheral edge of the substrate 5 placed on the table 62 is R. When the substrate 5 is placed on the table 62 with the rotation axis line 62a aligned with the center of the substrate 5, the radius of the substrate 5 becomes R. In addition, assuming that a distance between the rotation axis line 62a of the table 62 and a center point T of the surface of the target 64 is OF and a height from the surface of the substrate 5 placed on the table 62 to the center point T of the surface of the target 64 is TS, the target 62 is arranged to substantially satisfy the following relationship:

R:OF:TS=100:175:190±20 (1)

For example, if the diameter of the substrate 5 is 200 mm, i.e., R=100 mm, thus OF=175 mm and TS=190 mm. If the diameter of the substrate 5 is 300 mm, i.e., R=150 mm, thus OF=262.5 mm and TS=285 mm. In addition, in a general sputtering apparatus, since it is easier to adjust TS than OF, a tolerance is set to TS. In addition, “substantially satisfy the following relationship (1)” means that a deviation of 5% or so of the ratio of R:OF:TS from the relationship (1) is included in the technical scope of the invention. This deviation is ±10 mm or so as the tolerance of OF.

In addition, the rotation axis line 62a of the table 62 on which the substrate 5 is placed is arranged on the same plane as a normal line 64a passing through the center point T of the surface of the target 64 (cathode surface), intersecting with each other. In addition, the target 64 is arranged so that an intersection angle θ satisfies the following relationship:

θ=22°±2° (2)

When θ falls within this range, the intersection of the normal line 64a passing through the center point T of the target 64 and the surface of the substrate 5 is located within a range of not more than 5 mm from the peripheral edge of the substrate 5. For example, if θ=22° and the diameter of the substrate 5 is 200 mm, a position of 2 mm from the peripheral edge of the substrate 5 becomes the intersection.

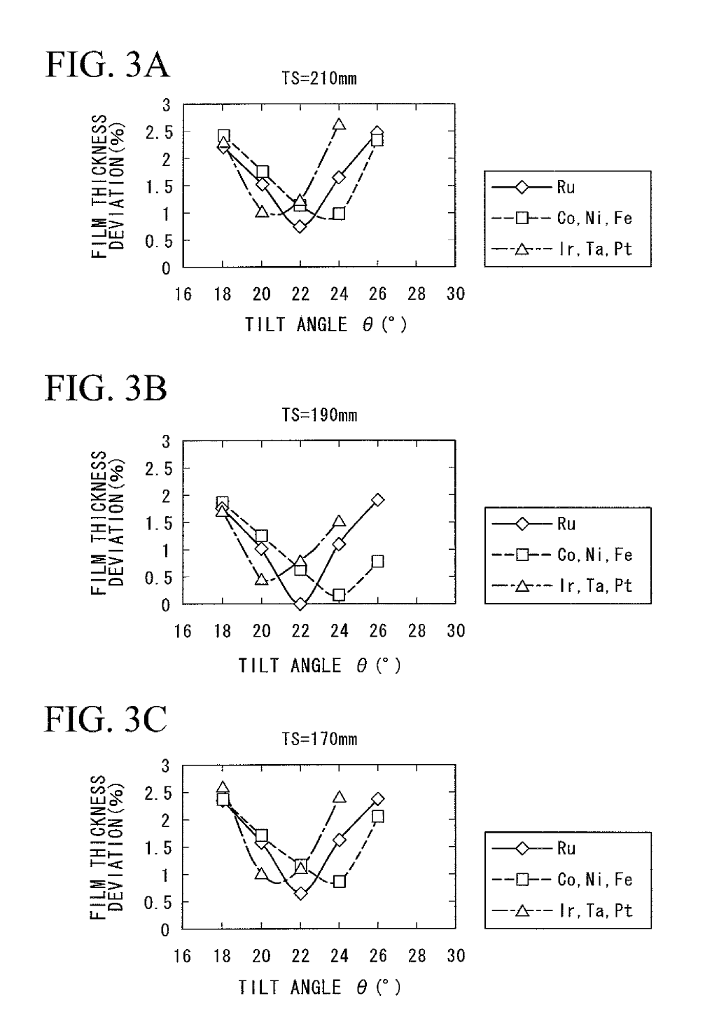

FIGS. 3A to 3C are graphs showing relationships between the tilt angle θ of the target and a film thickness deviation in sputter film formation of various metal materials. In all the figures, a vertical axis represents a ratio (%) of standard deviation σ of the film thickness deviation to film thickness. An atomic weight of Ru (Ruthenium) is about 101, an atomic weight of Co, Ni and Fe is about 56˜59, and an atomic weight of Ir, Ta and Pt is about 181˜195. Graphs are plotted for each element having the same atomic weight. FIG. 3A shows a case in which TS=210 mm, FIG. 3B shows a case in which TS=190 mm, and FIG. 3C shows a case in which TS=170 mm.

When TS=190 mm, it can be seen from FIG. 3B that the film thickness deviation of each element is minimal in the range of θ=22°±2°. In the film formation of Ru, the film thickness deviation is nearly 0% at θ=22°, thereby achieving a very uniform film forming process. In the film formation of Co, Ni and Fe having the atomic weight smaller than that of Ru, the film thickness deviation is about 0.1% at θ=24°, and, in the film formation of Ir, Ta and Pt having the atomic weight larger than that of Ru, the film thickness deviation is about 0.5% at θ=20°. Accordingly, in all cases, the film thickness deviations can be reduced to be equal to or less than 1%.

In addition, when TS=210 mm, it can be seen from FIG. 3A that the film thickness deviation of each element is minimal in the range of θ=22°±2°. It is likely that, for all elements, the film thickness deviations can be reduced to be equal to or less than 1%.

In addition, when TS=170 mm, it can be seen from FIG. 3C that the film thickness deviation of each element is minimal in the range of θ=22°±2°. It is likely that, for all elements, the film thickness deviations can be reduced to be equal to or less than 1%.

Accordingly, uniformity of the film forming process for the substrate can be improved by arranging the target to satisfy the above relationships (1) and (2).

Returning to FIG. 1B, a shield plate (a side shield plate (first shield plate) 71 and a lower shield plate (second shield plate) 72) made of stainless steel or the like is provided to surround the table 62 and the target 64. The side shield plate 71 has a cylindrical shape and extends from a ceiling of the chamber 61 to the table 62. A center axis of the side shield plate 71 is arranged to be identical with the rotation axis line 62a of the table 62. For example, the diameter of the side shield plate 71 is set to be 440 mm. In addition, the lower shield plate 72 is provided to extend from the lower end (end of the first region) of the side shield plate 71 to the peripheral edge of the table 62. The lower shield plate 72 has a funnel shape, and its center axis is arranged to be identical with the rotation axis line 62a of the table 62.

In addition, the sputter processing chamber 70 is defined by a space surrounded by the substrate surface of the substrate 5 placed on the table 62, the lower shield plate 72, the side shield plate 71 and the ceiling of the chamber 61. That is, the substrate 5 is held by the table 62 with the substrate surface directed to the interior of the sputter processing chamber 70. The sputter processing chamber 70 has an axially symmetrical shape, and its symmetrical axis is arranged to be identical with the rotation axis line 62a of the table 62. Accordingly, every parts of the substrate 5 can be applied sputter processing uniformly; thereby reducing the film thickness deviations. In addition, a sputter gas supplying device (not shown) to supply a sputter gas is provided within the sputter processing chamber 70. In addition, the chamber 61 is provided with an exhaust port 69 connected to an exhausting pump (not shown).

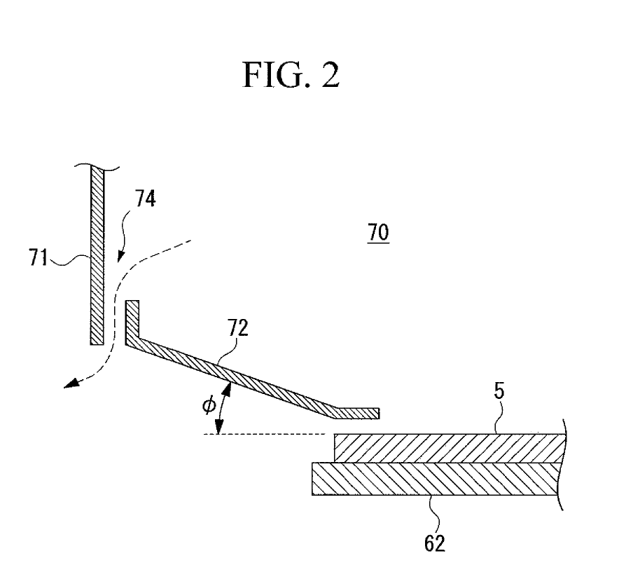

FIG. 2 is an enlarged view of portion B of FIG. 1B. As shown in FIG. 2, it is preferable that an angle φ between the surface of the substrate 5 placed on the table 62 and an inclined plane of the lower shield plate 72 be set to be not more than 20° and not less than 0°. This can prevent the uniformity of the film thickness at the peripheral edge of the substrate 5 from being deteriorated by the lower shield plate 72. In addition, an exhaust slit 74 is formed between the circumference of the lower shield plate 72 and the lower end of the side shield plate 71. The exhaust slit 74 is formed throughout the circumference of the sputter processing chamber 70. Thus, an exhaust flow passage within the sputter processing chamber 70 forms axial symmetry; thereby reducing the film thickness deviations in the substrate 5. In addition, an inner edge of the lower shield plate 72 is arranged at an inner side from the peripheral edge of the substrate 5 placed on the table 62. Thus, it is possible to prevent gas and the like within the sputter processing chamber 70 from being introduced into the side of the substrate 5, thereby preventing contamination of the substrate 5.

(Film Forming Method)

Next, a method of forming a film on the surface of the substrate using the sputtering apparatus according to the embodiment of the present invention will be described with reference to FIGS. 1A and 1B.

First, the substrate 5 is placed on the table 62 and the sputter processing chamber 70 forms a vacuum (vacuum forming process). Next, a sputter gas such as argon or the like is introduced into the sputter processing chamber 70 to generate plasma (film forming process). Then, ions of the sputter gas collide with the target 64 as the cathode, and atoms of a film forming material are emitted from the target 64 and are attached to the substrate 5. At that time, when a magnetic field is applied to the surface of the target to generate high density plasma near the target, a film forming speed increases.

The film forming process is performed while rotating the substrate 5 using the table 62. The rotational speed of the substrate 5 is preferably not less than 30 rpm, more preferably 120 rpm or so. This is because, if the rotational speed is low, the film thickness deviations in the circumference of the substrate are not averaged, and accordingly, the film thickness deviation in the circumference of the substrate is generated. Particularly, if a film is formed to be thin at a low film forming speed, an effect of the film thickness deviations is significant. For example, if a film is formed with a film thickness of equal to or less than 100 Angstroms at a film forming speed of about 1 Angstrom per second, and if the rotational speed of the substrate 5 is less than 60 rpm, the film thickness deviations may be equal to or more than 1%.

In a range of practical film forming conditions, the film thickness deviations may be restricted to be equal to or less than 1% by setting the rotational speed of the substrate 5 to be equal to or more than 30 rpm.

In addition, although the rotational speed of equal to or more than 120 rpm does not show a distinguishable effect, it is confirmed from the arrangement of the apparatus that the maximum rotational speed is 300 rpm. Thus, it can be said that the rotational speed of equal to or more than 30 rpm and equal to or less than 300 rpm is suitable.

As described in detail above, the sputtering apparatus and the film forming method according to the embodiment of the present invention can reduce the film thickness deviations. That is, the film thickness deviation of equal to or less than 1% can be achieved for various kinds of target materials. For example, the film thickness deviation of 0.26% can be achieved for Al, the film thickness deviation of 0.42% can be achieved for Ta, the film thickness deviation of 0.71% can be achieved for PtMn, the film thickness deviation of 0.47% can be achieved for CoFe, the film thickness deviation of 0.39% can be achieved for NiFe, and the film thickness deviation of 0.20% can be achieved for Ru. Thus, uniform film thickness can be obtained for CoFe, NiTe, PtMn, IrMn and the like used as magnetic materials, or Ru and the like as non-magnetic metal, as well as Cu, Ta, Al and the like frequently used for semiconductor devices.

In addition, using the sputtering apparatus and the film forming method according to the embodiment of the present invention, film thickness deviations in layers can be reduced by forming a magnetic multi-layered film. Particularly, in formation of a tunnel junction device, since a tunnel barrier layer can be flatly formed, a difference of resistance of the tunnel junction device depending on positions on the substrate can be reduced. In addition, since a free layer can be flatly formed, magnetization of the free layer in the tunnel junction device can become uniform, thereby reducing a deviation of a magnetic field applied in order to reverse a magnetization direction of the free layer. This is very important in fabricating MRAM devices having uniform performance on a large wafer.

The technical scope of the present invention is not limited to the above-described embodiments, but is to be construed to include various modifications of the embodiments without departing from the spirit of the present invention. That is, detailed materials, constructions, manufacturing conditions and so on described and shown in the embodiments are only by way of an example, but may be modified in various ways.

For example, although it has been illustrated in the above embodiment that the table is arranged near the bottom of the chamber and the target is arranged near the ceiling of the chamber, the target may be arranged near the bottom of the chamber and the table may be arranged near the ceiling of the chamber. In addition, although it has been illustrated in the above embodiment that the substrate is arranged with the center of the substrate being aligned with the rotation axis line of the table, the substrate may be arranged with the center of the substrate being offset with respect to the rotation axis line of the table. In addition, a film forming process may be simultaneously performed for a plurality of substrates placed on the table.

### INDUSTRIAL APPLICABILITY

The present invention is adapted to the formation of a film constituting a semiconductor device, such as a GMR spin valve constituting a magnetic head, a TMR device constituting a MRAM and so on.

What is claimed is:

1. A sputtering apparatus for performing a film forming process on a substrate surface of a disk-like substrate while rotating the substrate around a rotation axis line, the sputter apparatus comprising:
a chamber having a sputter processing chamber formed therein;
a table that is provided in a first region of the chamber and rotates the substrate in a plane parallel to the substrate surface around the rotation axis line while holding the substrate with the substrate surface directed to an interior of the sputter processing chamber; and
a sputtering cathode that is provided at a position spaced from the rotation axis line in a second region of the chamber, the second region being located at the opposite side to the first region with the sputter processing chamber interposed therebetween, and has a cathode surface facing the substrate in the sputter processing chamber, wherein
assuming that a distance between the rotation axis line and a peripheral edge of the substrate is R, a distance between the rotation axis line and a center point of the cathode surface is OF, and a height from the substrate surface to the center point of the cathode surface is TS, the following relationship is substantially satisfied,
R:OF:TS=100:175:190±20; and
the rotation axis line intersects a normal line passing through the center point of the cathode surface, and an intersection angle thereof falls within a range of 22°±2°.

2. The sputtering apparatus according to claim 1, wherein a shield plate which surrounds the substrate is arranged with axial symmetry around the rotation axis line, and wherein
the sputter processing chamber is defined by an inner space surrounded by the shield plate and the substrate surface.

3. The sputtering apparatus according to claim 2, wherein the shield plate includes:
a first shield plate that has a cylindrical shape and extends from the second region to the first region; and
a second shield plate that has a funnel shape and extends from an end portion of the first shield plate in the first region to a peripheral edge of the substrate, wherein
an inclined angle of the second shield plate with respect to the substrate surface is set to equal to or less than 20°.

4. A method of forming a film using a sputtering apparatus according to claim 1, comprising:
a vacuum forming step of vacuumizing the sputter processing chamber with the substrate being placed on the table; and
a film forming step of forming the film on the substrate surface by introducing a sputter gas into the sputter processing chamber and generating plasma while rotating the substrate using the table.

5. The method of forming a film according to claim 4, wherein the substrate is rotated with a rotational speed of not less than 30 rpm.

6. The method of forming a film according to claim 4, wherein a multi-layered film including a magnetic layer is formed in the film forming step.
